(19) United States
(12) Patent Application Publication
(10) Pub. No.: US 2025/0022767 A1
(43) Pub. Date: Jan. 16, 2025

(54) CHIP-ON-FILM PACKAGE STRUCTURE

(71) Applicant: SDP Global (China) Co., Ltd., Guangzhou City (CN)

(72) Inventor: TIAN-XUN LIANG, Guangzhou City (CN)

(21) Appl. No.: 18/769,468

(22) Filed: Jul. 11, 2024

(30) Foreign Application Priority Data
Jul. 11, 2023 (CN) 202321824450.3

(51) Int. Cl. H01L 23/367; H01L 23/495

(52) U.S. Cl. CPC H01L 23/3675; H01L 23/49572

(57) ABSTRACT

The present utility model provides a chip-on-film packaging structure, comprising a chip-on-film package body and a heat dissipating sheet configured for covering the chip-on-film package body and dissipating heat of a chip contained in the chip-on-film package body, wherein the heat dissipating sheet comprises a main attachment area and a bulge suppression portion, the main attachment area is covered and bonded to an upper surface of the chip, the bulge suppression portion is disposed at an outer periphery of the main attachment area to prevent the heat dissipating sheet at the four corners of the chip from bulging. The present utility model can smooth the bulge at the corner of the heat dissipating sheet and make the heat dissipating sheet stick to the four side surfaces of the chip more tightly, thereby improving bonding reliability and enhancing heat dissipation efficiency.

### TECHNICAL FIELD

The present utility model relates to the field of semiconductor packaging, and in particular, to a heat dissipation sheet and a chip-on-film packaging structure applied in chip on film packaging.

### BACKGROUND

Chip on Film (COF) packages are a chip-on-film construction technology that fixes chips to flexible substrates. Chips generate heat when the chip-on-film package is operated by being connected to other circuit structures. With the miniaturization of integrated circuits, as the functions of chips become more integrated, more heat is generated by the chips, and it is necessary to add heat dissipation mechanisms to help the chips dissipate heat, so as to avoid damage to the chips, flexible substrates, etc.

In the prior art, it is proposed to arrange heat dissipation sheets of a metal material above a chip of a chip-on-film package and/or below a flexible substrate to achieve quicker heat dissipation of the chip. The heat dissipation sheets are attached to and contacted with the chip-on-film package member, so as to transfer the heat of the chip to the air. Therefore, the heat dissipation sheets are attached to the chip-on-film package member as closely as possible to facilitate heat dissipation.

However, in the prior art, for heat dissipation sheets attached above a chip of a chip-on-film package, as shown in FIGS. 1 and 2, a heat dissipation sheet 3′ used in the prior art is attached to a chip 1 of a chip-on-film package, the heat dissipation sheet 3′ comprises a main attaching area S1 corresponding to the upper surface of the chip 1, a side attaching area S2 surrounding the main attaching area S1, and a substrate attaching area S3 surrounding the side attaching area S2. The side attaching area S2 is an area to be attached to a side of the chip 1, but the heat dissipation sheet 3′ is attached to the chip package in a press fit manner, When the heat dissipation sheet 3′ is attached to the chip 1, because the chip 1 itself has a certain height, the heat dissipation sheet 3′ cannot conform to the shape of the chip 1 and closely attach to the four side surfaces of the chip 1, furthermore, the positions corresponding to the four corners of the chip 1 are swollen due to partial redundancy of the heat dissipation sheet 3′ corresponding to the two adjacent side surfaces of the chip 1, as a result, a gap is formed in the side attaching area S2, which is adverse to the heat dissipation efficiency. Furthermore, the inventors of the present disclosure have found that, in order to shorten the width of the side attaching area S2 in the conventional heat dissipating sheet 3′, that is, to shorten the distance between the boundary of the side attaching area S2 and the boundary of the main attaching area S1, the bulge at the positions corresponding to the four corners of the chip 1 creates a larger range, and sometimes the bulge even extends to the edge of the heat dissipation sheet 3′, as a result, the attachment reliability between the heat dissipation sheet 3′ and the substrate 2 is reduced, which may affect the heat dissipation efficiency.

Accordingly, a heat dissipation sheet and a package structure with an improved heat dissipation efficiency are needed.

### SUMMARY

The present disclosure is based on the above-described problems.

One aspect of the present utility model provide a chip-on-film packaging structure, comprising a chip-on-film package body and a heat dissipating sheet configured for covering the chip-on-film package body and dissipating heat of a chip contained in the chip-on-film package body, wherein the heat dissipating sheet comprises a main attachment area and a bulge suppression portion, the main attachment area is covered and bonded to an upper surface of the chip, the bulge suppression portion is disposed at an outer periphery of the main attachment area to prevent the heat dissipating sheet at the four corners of the chip from bulging.

Further, one aspect of the present utility model also has the following constitution: the bulge suppression portion comprises a first portion, which are hole lines or kerfs extending outward from two opposite corner portions of the main attachment area, and the bulge suppression portion is in an area defined by extension lines extending outward from long sides and short sides of the main attachment area.

Further, one aspect of the present utility model also has the following constitution: the bulge suppression portion further comprises a second portion, which are short-side hole lines overlapping and extending along the short sides of the main attachment area, and an amount of extension of the second portion from the corner portion is equal to or greater than a height of the chip.

Further, one aspect of the present utility model also has the following constitution: the bulge suppression portion comprises a first set of the bulge suppression portions and a second set of the bulge suppression portions which are alternately arranged along a long side direction of the main attachment area, the first group of the bulge suppression portions and the second group of the bulge suppression portions are a plurality of hole lines or a plurality of kerfs which are parallel to each other, the first group of the bulge suppression portions and the second group of the bulge suppression portions are alternately provided, when viewed from top to bottom along a width direction of the heat dissipating sheet, the heat dissipating sheet sequentially comprises a first area, a third area, and a second area, lower portions of the first set of the bulge suppression portions and upper portions of the second set of the bulge suppression portions are alternately arranged at the third area, and lower portions of the second set of the bulge suppression portions are arranged at the second area, and the chip is arranged at the first area or the second area.

Further, one aspect of the present utility model also has the following constitution: the plurality of hole lines or the plurality of kerfs of the first set of the bulge suppression portions and the second set of the bulge suppression portions are perpendicular to the long side direction of the main attachment area.

Further, one aspect of the present utility model also has the following constitution: a pitch is arranged between the main attachment area and the third area, the pitch is above a height of the chip.

Further, one aspect of the present utility model also has the following constitution: the heat dissipating sheet comprises a first notch disposed at an outer side of at least one long side of the main attachment area; and a second notch opened from the first notch to a direction away from the main attachment area, the first notch has an elongated shape having a length larger than a length of the main attachment area, and is disposed along the long side of the main attachment area, the bulge suppression portion is configured by at least the first notch and the second notch.

Further, one aspect of the present utility model also has the following constitution: in a long side direction of the main attachment area, a width by which two ends of the first notch exceeds that of the main attachment area is equal to or greater than a height of the chip, a pitch is arranged between the main attachment area and the third area, the pitch is above the height of the chip.

Further, one aspect of the present utility model also has the following constitution: the heat dissipating sheet further comprises two third notches provided at outer sides of two short sides of the main attachment area and an opening toward a direction away from the main attachment area, the third notches are not communicated with the first notch, and the bulge suppression portion is configured by at least the first notch, the second notch and the third notches.

Further, one aspect of the present utility model also has the following constitution: the bulge suppression portion is an opening, the opening has a shape of any one of a circular hole, an oval hole, and a rectangular hole, and the opening of the bulge suppression portion extends into two ends of the main attachment area, so that an entire short side of the chip is exposed.

### BRIEF DESCRIPTION OF DRAWINGS

FIG. 1 is a schematic top view of a chip-on-film package applying a heat dissipation sheet in prior art.

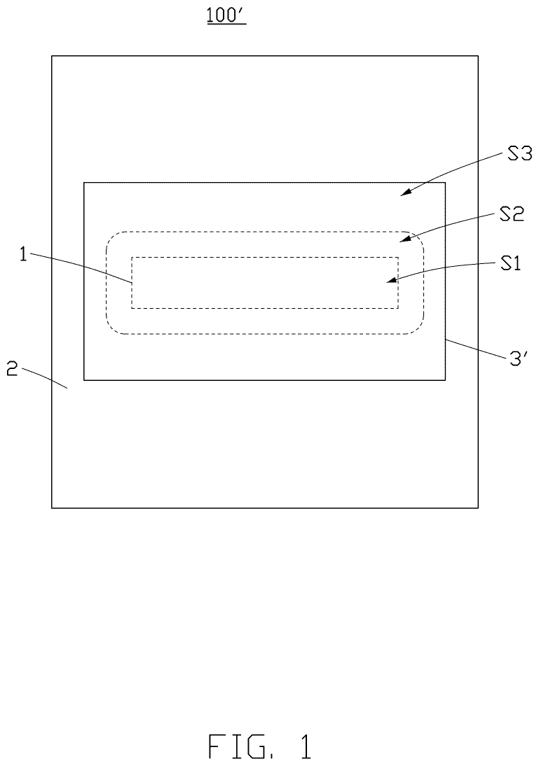

FIG. 2 is a cross-sectional view of FIG. 1.

FIG. 3 is a schematic top view illustrating a package structure according to a first embodiment of the present disclosure.

FIG. 4 is a schematic top view illustrating the package structure according to another example implementation of the first embodiment of the present disclosure.

FIG. 5 is a schematic top view illustrating the package structure according to a second embodiment of the present disclosure.

FIG. 6 is a schematic top view illustrating the package structure according to a third embodiment of the present disclosure.

FIG. 7 is a schematic top view illustrating the package structure according to another example implementation of the third embodiment of the present disclosure.

FIG. 8 is a schematic top view illustrating the package structure according to a fourth embodiment of the present disclosure.

### REFERENCE SIGNS LIST

100, 100a, 100a′, 100b, 100c, 100c′, 100d, 100′ Chip-On-Film Package Structure
1 Chip
2 Substrate
21 Base Material
22 Conductive Pattern (Trace)
23 Solder Resist Layer
3,3a,3a′,3b,3c,3c′,3d,3′ heat dissipation sheet
31 First Bulge Suppression Portion
32 Second Bulge Suppression Portion
33 Third Bulge Suppression Portion
34 Fourth Bulge Suppression Portion
35 Fifth Bulge Suppression Portion
4 Thermal Conductive Adhesive
S1 Main Attachment Area
S2 Side Attachment Area
S3 Substrate Attachment Area
K1 First Notch
K2 Second Notch
K3 Third Notch
K4 Fourth Notch
K5 Fifth Notch
K6 Sixth Notch

### DETAILED DESCRIPTION

In order to make the above objects, features and advantages of the present utility model more clear and easy to understand, the embodiments of the present utility model will be described in detail below with reference to the accompanying drawings, but the specific configuration is not limited to the embodiments, and designs and the like within a scope that does not depart from the gist of the present utility model are also included in the scope of protection.

For the sake of convenience in description, unless otherwise specified, components having the same reference numbers indicate components having the same functions, and the description thereof may be omitted. In the drawings referred to below, configurations are simplified or schematically shown for easy understanding of the description, or some of the components are omitted. The dimensional ratios between the components shown in the drawings do not necessarily represent actual dimensional ratios.

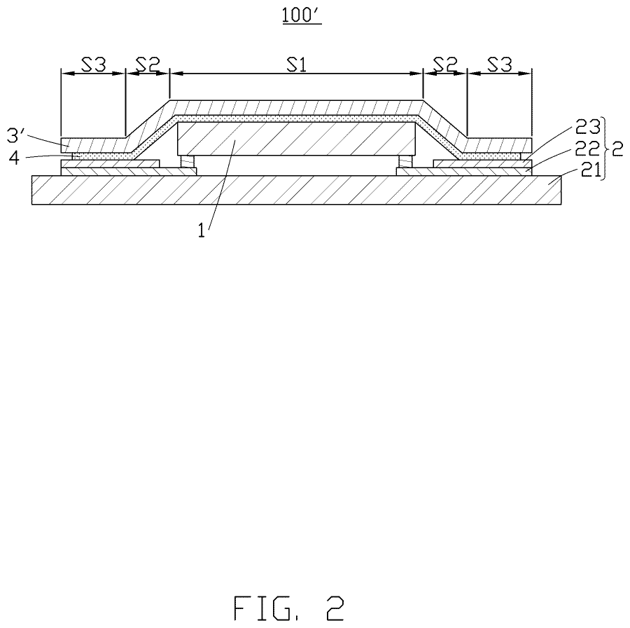

In the present utility model, the chip-on-film package body used in the chip-on-film package structure 100 may have the same structure as that in the prior art. As shown in FIG. 2, the chip-on-film package body of the present utility model comprises a substrate 2 and a chip 1 arranged on the substrate 2. The substrate 2 may be a flexible substrate, and includes a base material 21, a conductive pattern (trace) 22 disposed on the base material 21, and a solder resist layer 23 covering the conductive pattern 22. The base material 21 may be a film base material having flexibility. The conductive pattern 22 electrically connects the chip 1 to other circuits by being connected to pins that the chip 1 has to fulfill the function of the chip 1. The solder resist layer 23 may be an insulating ink.

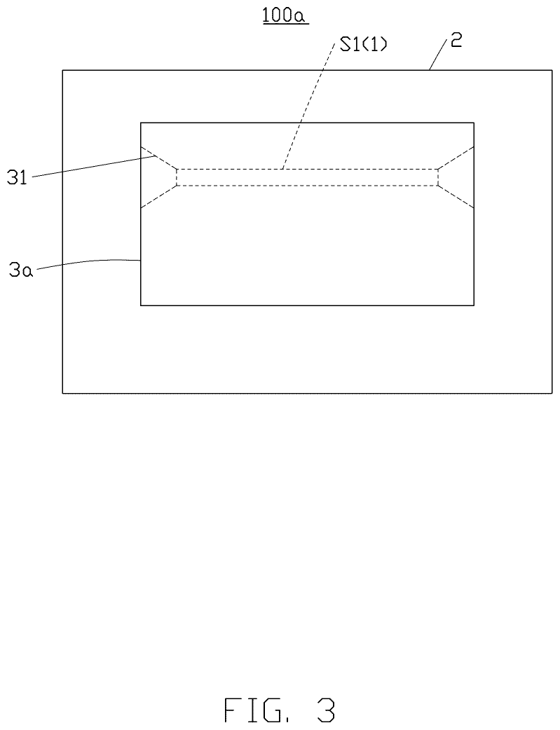

As follows, FIGS. 3 to 8 are schematic diagrams illustrating the chip-on-film package structure 100 of the present utility model. In this specification, a heat dissipation sheet is described as “3” and a chip-on-film package structure is described as “100” without distinguishing between embodiments. The chip-on-film package structure 100 includes the chip-on-film package body described above and a heat dissipation sheet 3 covering the chip 1 on a side of the substrate 2 where the chip 1 is disposed. Furthermore, a thermal conductive adhesive 4 is further included between the heat dissipation sheet 3 and the chip-on-film package body. The thermal conductive adhesive 4 can be pre-coated on the heat dissipation sheet 3 by using a material in the prior art. When the heat dissipation sheet 3 is attached to the chip-on-film package body, a surface of one side on which the thermal conductive adhesive 4 is coated faces the chip-on-film package body to be attached and pressed together.

In addition, the chip-on-film package structure 100 may also include a back side heat dissipating sheets covering a surface opposite to the chip 1. The shape of the back side heat dissipating sheet is not limited, and a structure in the prior art may be used, or may be set according to a back side conductive pattern of the substrate 2.

### First Embodiment

As follows, the first embodiment of the present utility model is specifically described with reference to FIG. 3.

The chip-on-film package structure 100a of this embodiment includes a heat dissipation sheet 3a. As shown in FIG. 3, the heat dissipation sheet 3a is a rectangular sheet, and a material of the heat dissipation sheet 3a may be selected from at least one of copper, aluminum, graphite and other materials with good heat conduction capability. Similarly to the heat dissipating sheet 3′, the heat dissipating sheet 3a comprises a main attachment area S1 attached to the upper surface of the chip 1, a side attachment area S2 extending from each end of the main attachment area S1 to a direction away from the main attachment area S1 and surrounding the main attachment area S1, and a substrate attachment area S3 extending from each end of the side attachment area S2 to a direction away from the main attachment area S1.

The main attachment area S1 has a rectangular shape corresponding to the shape of the upper surface of the chip 1. In addition, the pitch between the side attachment area S2 and the main attachment area S1, i.e., the width of the side attachment area S2, is equal to or more than the height of the chip 1, and the outer areas of the four corners of the main attachment area S1 in the side attachment area S2 are defined as “bulging area”, in which the problem of bulging as mentioned in the technical problem occurs.

The heat dissipating sheet 3a of the present embodiment includes, at least in a bulging area of the outer periphery of the main attachment area S1, four first bulge suppression portions 31 respectively extending outward from the four corners of the main attachment area S1. The four first bulge suppression portions 31 are hole lines indicated by oblique dashed lines or kerfs cut along the oblique dashed lines in FIG. 3, which extend respectively outward from four corners of the main attachment area S1. For example, the first bulge suppression portion 31 in the upper left corner extends in the upper left direction from the upper left corner of the main attachment area S1. The first bulge suppression portion 31 is located in the area formed by the extension lines of the longer side and the shorter side of the main attachment area S1 towards outer side, and preferably, the angle defined by the first bulge suppression portion 31 with respect to the extension line of the long side of the main attachment area S1 is 30 degrees to 60 degrees, and more preferably 45 degrees. In addition, the first bulge suppression portion 31 has a length equal to or greater than the height of the chip 1, in other words, the first bulge suppression portion 31 reaches at least the boundary of the side attachment area S2. Further, the first bulge suppressing portion 31 may also extend further up to the edge of the heat dissipation sheets 3a.

According to the present embodiment, by forming the first bulge suppression portion 31 with the hole lines or the kerfs in the heat dissipation sheets 3a, when the heat dissipating sheet 3a is attached to the chip-on-film package body and pressed together, air between the heat dissipating sheet 3a and the chip-on-film package body can be discharged from the first bulge suppression portion 31 while providing greater pressing deformation, in this way, it is beneficial to smooth the bulge caused by partial redundancy of the heat dissipating sheet 3a corresponding to the two adjacent side surfaces of the chip 1 in the side attachment area S2, in addition, the heat dissipation sheet 3a can be more tightly attached to four side surfaces of the chip 1, thereby improving attachment reliability and increasing heat dissipation efficiency.

### Another Example of the First Embodiment

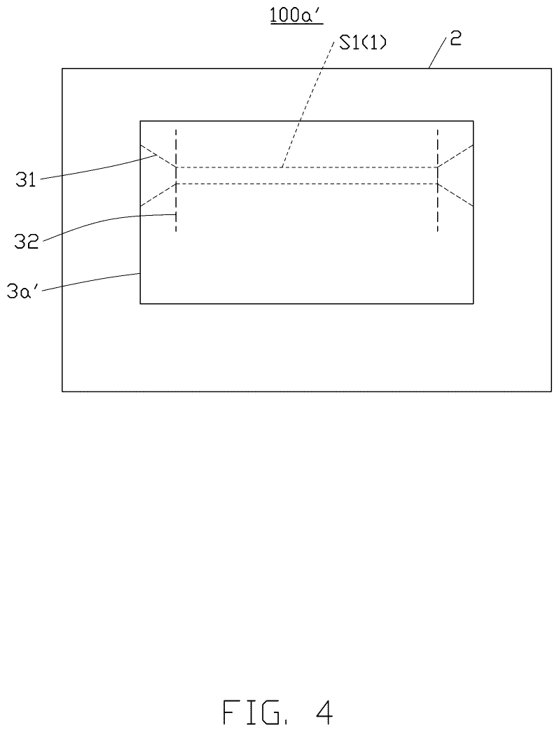

As shown in FIG. 4, the first embodiment may also include two second bulge suppression portions 32 overlapped and extended along the two short edges of the main attachment area S1 based on the example described above with reference to FIG. 3, and the second bulge suppression portions 32 are hole lines shown in FIG. 4 or kerfs cut along the inclined dotted line shown in FIG. 4. The second bulge suppression portion 32 is provided at least by the height of the chip 1 extending from the corner portion.

In this example, by providing the first bulge suppression portion 31 and the second bulge suppression portion 32, compared with the example in FIG. 3, the heat dissipating sheet 3a′ can be more closely attached to the four side surfaces of the chip 1 in the side attachment area S2, thereby improving the attachment reliability and further increasing the heat dissipation efficiency.

### Second Embodiment

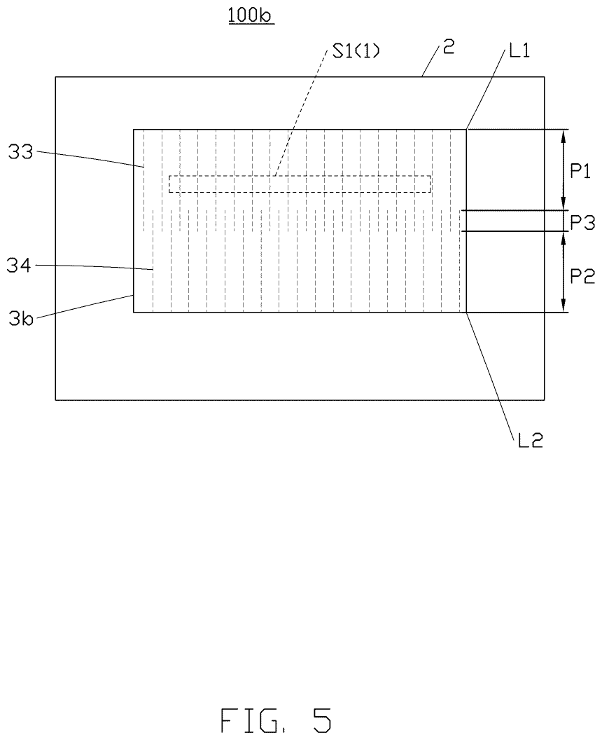

FIG. 5 is a schematic top view illustrating a chip-on-film package structure 100b according to the present embodiment. In the present embodiment, the entirety of the heat dissipating sheet 3b includes a plurality of third bulge suppression portions 33 and a plurality of fourth bulge suppression portions 34 alternatively provided along the long side direction of the main attachment area S1. Each of the plurality of third bulge suppression portions 33 is parallel to each other, each of the plurality of fourth bulge suppression portions 34 is parallel to each other, the plurality of third bulge suppression portions 33 are also parallel to the plurality of fourth bulge suppression portions 34, and the plurality of third bulge suppression portions 33 and the plurality of fourth bulge suppression portions 34 are arranged alternately, so that the heat dissipating sheet 3b is deformed and closely attached to the main attachment area S1. The plurality of third bulge suppression portions 33 are a plurality of hole lines or a plurality of kerfs extending inwardly from a first side L1 of the heat dissipating sheet 3b which is opposed to one long side of the main attachment area S1, and the plurality of fourth bulge suppression portions 34 are a plurality of hole lines or a plurality of kerfs extending inwardly from a second side L2 of the heat dissipating sheet 3b which is opposed to the other long side of the main attachment area S1.

At least one of the plurality of third bulge suppression portions 33 and the plurality of fourth bulge suppression portions 34 extends over half the width (e.g., ⅔ of the width) of the heat dissipating sheet 3b. Thus, the first area P1, the third area P3, and the second area P2 are included in this order as viewed from above along the width direction of the heat dissipating sheet 3b, the upper portion of the third bulge suppression portion 33 is in the first area P1, the lower portion of the third bulge suppression portion 33 and the upper portion of the fourth bulge suppression portion 34 are alternately arranged in the third area P3, and the lower portion of the fourth bulge suppression portion 34 is in the second area P2. In the example shown in FIG. 5, the lengths of the first area P1 plus the third area P3 are the length of the third bulge suppression portion 33, and the lengths of the second area P2 plus the third area P3 are the length of the fourth bulge suppression portion 34.

In the example of the present embodiment, the chip 1 is disposed in the first area P1, and the distance between the side attachment area S2 and the third area P3 is not less than the height of the chip 1. Herein, a pitch between the main attachment area S1 and the third area P3 may be set to double the height of the chip 1 or more.

In addition, although the plurality of third bulge suppression portions 33 and the plurality of fourth bulge suppression portions 34 are shown as extending along the short-side direction of the main attachment area S1, the present utility model is not limited thereto, and the plurality of third bulge suppression portions 33 and the plurality of fourth bulge suppression portions 34 may be provided to be inclined with respect to the short-side direction, and may be appropriately changed according to actual applications. In addition, the chip 1 may also be disposed in the third area P3, and when disposed in this area, the positional conditions are the same as those in the first area P1. In addition, the pitches between which the plurality of third bulge suppression portions 33 and the plurality of fourth bulge suppression portions 34 alternate with each other may be the same, may not be all the same, may be completely different, and may be changed as appropriate depending on the actual application.

In addition, the present embodiment is not limited to the configuration in which two sets of the bulge suppression portions are provided in the heat dissipating sheet 3b, and three sets of the bulge suppression portions may be provided, wherein the three sets of the bulge suppression portions are arranged in three rows from up to down, The first set of the bulge suppression portions located on the lower side and the second set of the bulge suppression portions located on the center are arranged alternately, when the heat dissipating sheet 3 is divided into five areas from top to bottom, The second set of bulge suppression portions are provided in the second to fourth areas, and the third set of bulge suppression portions are provided in the fourth to fifth areas. In this composition, the chip 1 may be selectively disposed in the first area, the third area and the fifth area, preferably in the third area, and the third area is an area between the one set of the bulge suppression portions and the other set of the bulge suppression portions being alternately disposed and the other set of the bulge suppression portions and the last set of the bulge suppression portions being alternately disposed.

According to the present embodiment, by forming the plurality of third bulge suppression portions 33 and the plurality of fourth bulge suppression portions 34 with the hole lines or the kerfs in the heat dissipation sheets 3b, when the heat dissipating sheet 3b is attached to the chip-on-film package body and pressed together, air between the heat dissipating sheet 3b and the chip-on-film package body can be discharged from the plurality of third bulge suppression portions 33 and the plurality of fourth bulge suppression portions 34 while providing greater pressing deformation, in this way, it is beneficial to smooth the bulge caused by partial redundancy of the heat dissipating sheet 3b corresponding to the two adjacent side surfaces of the chip 1 in the side attachment area S2, in addition, the heat dissipation sheet 3a can be more tightly attached to four side surfaces of the chip 1, thereby improving attachment reliability and increasing heat dissipation efficiency.

### Third Embodiment

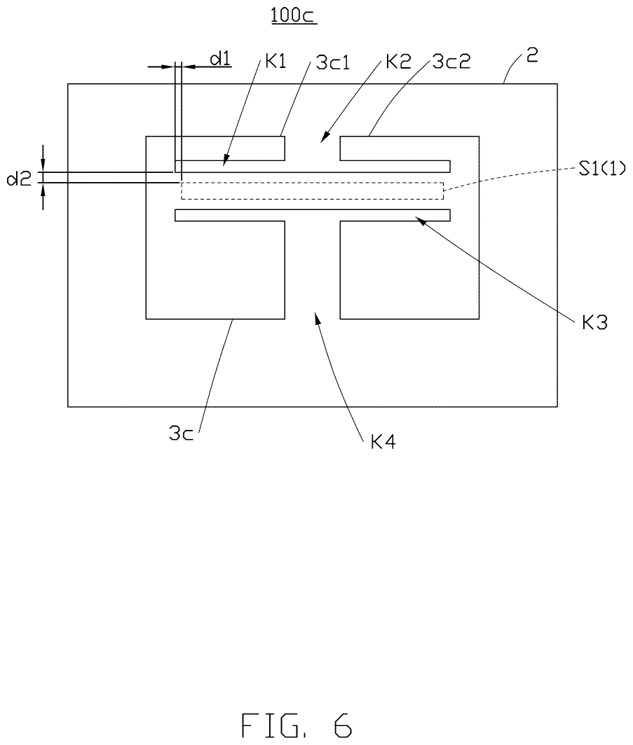

FIG. 6 is a schematic top view illustrating a chip-on-film package structure 100c according to the present embodiment. In the present embodiment, the heat dissipating sheet 3c includes a first notch K1 disposed on the outer side of one long side (the upper side in the figure) of the main attachment area S1 and a second notch K2 opened to a direction away from the main attachment area S1 from the first notch K1.

As follows, detailed settings of the shape and size of the first notch K1 and the second notch K2 will be described in detail. The first notch K1 has an elongated shape (for example, a matrix shape, a racetrack shape, etc.) exceeding the length of the main attachment area S1, and is disposed along the long side of the main attachment area S1. In the long side direction of the main attachment area S1, a width d1 by which each end of the first notch K1 exceeds that of the main attachment area S1 is equal to or greater than the height of the chip 1. Furthermore, the distance d2 between the main attachment area S1 and the first notch K1 is also set to be greater than or equal to the height of the chip 1. More preferably, in order to prevent the heat dissipating sheet 3c from floating at the first notch K1 after attachment, the distance d2 is also set to be greater than or equal to twice the height of the chip 1. In addition, the second notch K2 opens in a direction away from the main attachment area S1 so as to open the upper part of the heat dissipating sheet 3c, however, the shape thereof is not particularly limited, and the upper part of the heat dissipating sheet 3c is divided into two portions 3cl and 3c2 by the second notch K2, furthermore, the shortest distance between the two parts 3cl and 3c2, i.e., the smallest dimension of the second notch K2 in the long side direction of the main attachment area S1, is set to be more than twice the height of the chip 1.

In addition, the heat dissipating sheet 3c further includes a third notch K3 disposed on the outer side of the other long side (the lower side in the figure) of the main attachment area S1 and a fourth notch K4 opened in a direction away from the main attachment area S1 from the third notch K3. The setting conditions for the shape and size of the third notch K3 and the fourth notch K4 can also satisfy the same conditions as the first notch K1 and the second notch K2. However, the first notch K1 and the third notch K3, the second notch K2 and the fourth notch K4 are not necessarily of the same size, and the second notch K2 and the fourth notch K4 can be appropriately set according to actual conditions.

According to the present embodiment, the first notch K1, the second notch K2, the third notch K3 and the fourth notch K4 are provided in the heat dissipating sheet 3c to satisfy the described dimensional conditions, so that the plurality of notches K1 to K4 can help the air between the chip-on-film package body and the heat dissipating piece 3c be discharged quickly when the heat dissipating piece 3c is attached to and pressed against the chip-on-film package body, furthermore, the part of the heat-dissipating sheet 3c, which is located at the left and right sides of the main attachment area S1, is folded inwards when they are attached, so that the redundancy of the heat dissipating sheet 3c is extended toward the notches, therefore, the notches K1 to K4 can function as the bulge suppression portion, providing a larger pressing deformation near the bulging area. With such a configuration, it is advantageous to smooth the bulge and make the heat dissipating sheet 3c stick to the four side surfaces of the chip 1 more tightly, thereby improving bonding reliability and enhancing heat dissipation efficiency.

### Another Example of the Third Embodiment

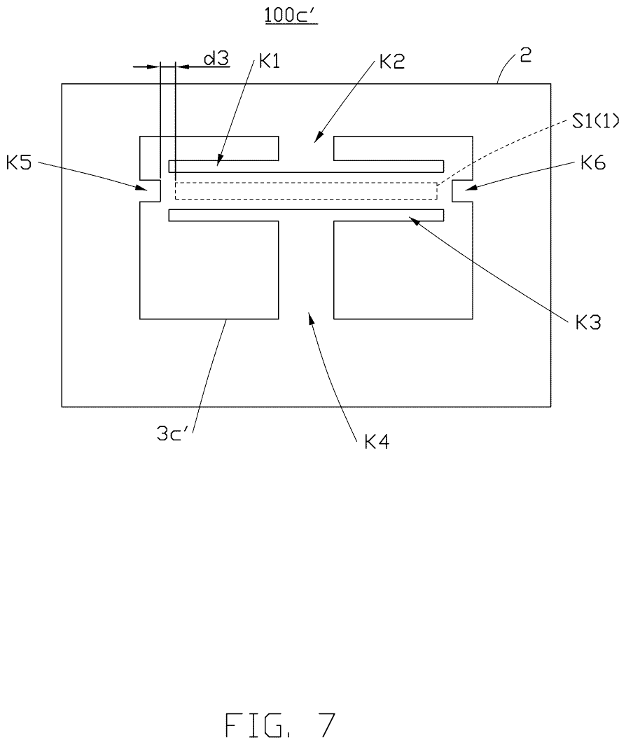

As shown in FIG. 7, in the third embodiment, basing on the example illustrated in FIG. 6, the heat dissipating sheet 3c′ of the chip-on-film package structure 100c′ further comprises a fifth notch K5 and a sixth notch K6 which are arranged outside the short edge of the main attachment area S1 and open toward the direction away from the main attachment area S1. And the fifth notch K5 and the sixth notch K6 are not communicated with the first notch K1 and the third notch K3.

As follows, detailed settings of the shape and size of the fifth notch K5 and the sixth notch K6 will be described in detail. The fifth notch K5 and the sixth notch K6 may be rectangular as shown in FIG. 7, but are not limited thereto, and may also be a part of a circle, an arc, or a trapezoid, and the distance d3 from the short side of the main attachment area S1 is set to be greater than or equal to the height of the chip 1, furthermore, the shortest distance between the two parts separated by the fifth notch K5 or the sixth notch K6, i.e., the smallest dimension of the fifth notch K5 or the sixth notch K6 in the short-side direction of the main attachment area S1, is set to be not less than twice the height of the chip 1.

Thus, in this example, in addition to the technical effects explained in the described example of the third embodiment, the fifth notch K5 and the sixth notch K6 can help the air between the chip-on-film package body and the heat dissipating piece 3c′ be discharged quickly when the heat dissipating piece 3c′ is attached to and pressed against the chip-on-film package body, furthermore, the part of the heat dissipating sheet 3c′, which is located outside the four edges of the main attachment area S1, is folded inwards when they are attached, so that the redundancy of the heat dissipating sheet 3c′ is extended toward the notches, therefore, the fifth notch K5 and the sixth notch K6 can function as the bulge suppression portion, providing a larger pressing deformation near the bulging area. With such a configuration, it is advantageous to smooth the bulge and make the heat dissipating sheet 3c′ stick to the four side surfaces of the chip 1 more tightly, thereby improving bonding reliability and enhancing heat dissipation efficiency.

### Fourth Embodiment

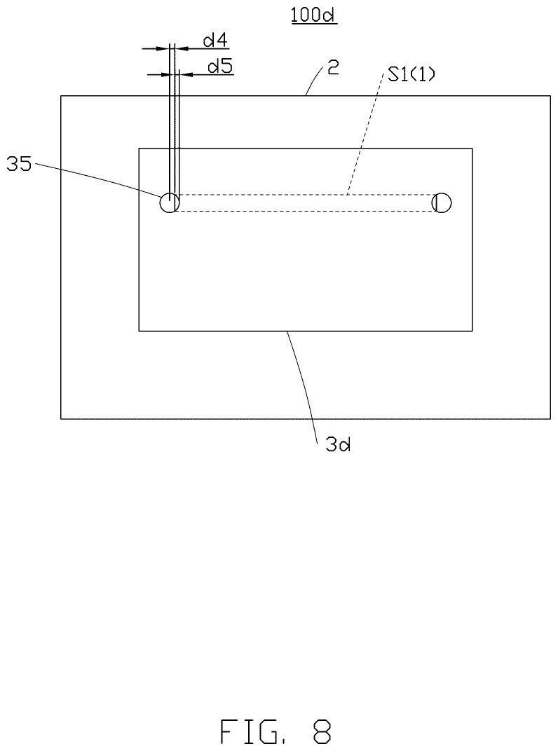

FIG. 8 is a schematic top view illustrating a chip-on-film package structure 100d according to the present embodiment. In the present embodiment, the heat dissipating sheet 3d includes two fifth bulge suppression portions 35. Part of the fifth bulge suppression portions 35 enters into both ends of the main attachment area S1. The bulge suppression portions 35 an opening, and the opening may have a shape of any one of a circular hole, an oval hole, and a rectangular hole, and the fifth bulge suppression portion 35 exposes the entire short side of the chip 1.

When the distance from the geometric center of the fifth bulge suppression portion 35 to the main attachment area S1 is set to d4 and the depth at which the fifth bulge suppression portion 35 enters the main attachment area S1 is set to d5, the depth d5 at which the fifth bulge suppression portion 35 enters the main attachment area S1 is limited to be shorter than the distance d4.

According to the present embodiment, by forming the fifth bulge suppression portion 35 with an opening in the heat dissipation sheets 3d, when the heat dissipating sheet 3d is attached to the chip-on-film package body and pressed together, air between the heat dissipating sheet 3d and the chip-on-film package body can be discharged from the fifth bulge suppression portion 35 while providing greater compression deformation at the bulging area, in this way, it is beneficial to smooth the bulge in the side attachment area S2, in addition, the heat dissipation sheet 3d can be more tightly attached to four side surfaces of the chip 1, thereby improving attachment reliability and increasing heat dissipation efficiency.

1. A chip-on-film packaging structure comprising a chip-on-film package body; and a heat dissipating sheet configured for covering the chip-on-film package body and dissipating heat of a chip contained in the chip-on-film package body,
wherein the heat dissipating sheet comprises a main attachment area and a bulge suppression portion,
the main attachment area is covered and bonded to an upper surface of the chip,
the bulge suppression portion is disposed at an outer periphery of the main attachment area to prevent the heat dissipating sheet at the four corners of the chip from bulging.

2. The chip-on-film package structure according to claim 1,
wherein the bulge suppression portion comprises a first portion, which are hole lines or kerfs extending outward from two opposite corner portions of the main attachment area, and the bulge suppression portion is in an area defined by extension lines extending outward from long sides and short sides of the main attachment area.

3. The chip-on-film package structure according to claim 2,
wherein the bulge suppression portion further comprises a second portion, which are short-side hole lines overlapping and extending along the short sides of the main attachment area, and an amount of extension of the second portion from the corner portion is equal to or greater than a height of the chip.

4. The chip-on-film package structure according to claim 1,
wherein the bulge suppression portion comprises a first set of the bulge suppression portions and a second set of the bulge suppression portions which are alternately arranged along a long side direction of the main attachment area, the first group of the bulge suppression portions and the second group of the bulge suppression portions are a plurality of hole lines or a plurality of kerfs which are parallel to each other, the first group of the bulge suppression portions and the second group of the bulge suppression portions are alternately provided,
when viewed from top to bottom along a width direction of the heat dissipating sheet, the heat dissipating sheet sequentially comprises a first area, a third area, and a second area, lower portions of the first set of the bulge suppression portions and upper portions of the second set of the bulge suppression portions are alternately arranged at the third area, and lower portions of the second set of the bulge suppression portions are arranged at the second area, and the chip is arranged at the first area or the second area.

5. The chip-on-film package structure according to claim 4,
wherein the plurality of hole lines or the plurality of kerfs of the first set of the bulge suppression portions and the second set of the bulge suppression portions are perpendicular to the long side direction of the main attachment area.

6. The chip-on-film package structure according to claim 4,
wherein a pitch is arranged between the main attachment area and the third area, the pitch is above a height of the chip.

7. The chip-on-film package structure according to claim 1,
wherein the heat dissipating sheet comprises a first notch disposed at an outer side of at least one long side of the main attachment area; and a second notch opened from the first notch to a direction away from the main attachment area,
the first notch has an elongated shape having a length larger than a length of the main attachment area, and is disposed along the long side of the main attachment area,
the bulge suppression portion is configured by at least the first notch and the second notch.

8. The chip-on-film package structure according to claim 7,
wherein in a long side direction of the main attachment area, a width defined by two ends of the first notch that extends beyond the main attachment area is equal to or greater than a height of the chip,
a pitch is arranged between the main attachment area and the third area, the pitch is above the height of the chip.

9. The chip-on-film package structure according to claim 7,
wherein the heat dissipating sheet further comprises two third notches provided at outer sides of two short sides of the main attachment area, and an opening toward a direction away from the main attachment area, the third notches are not communicated with the first notch, and the bulge suppression portion is configured by at least the first notch, the second notch and the third notches.

10. The chip-on-film package structure according to claim 1,
wherein the bulge suppression portion is an opening, the opening has a shape of any one of a circular hole, an oval hole, and a rectangular hole, and the opening of the bulge suppression portion extends into two ends of the main attachment area, so that an entire short side of the chip is exposed.
